(19) United States
(12) Patent Application Publication
(10) Pub. No.: US 2026/0064932 A1
(43) Pub. Date: Mar. 5, 2026

(54) CIRCUIT DESIGN OPTIMIZATION

(71) Applicant: International Business Machines Corporation, Armonk, NY (US)

(72) Inventors: Bijian Chen, Austin, TX (US); Alexander Joel Suess, Hopewell Junction, NY (US); Lakshmi N. Reddy, Mount Kisco, NY (US); Ying Zhou, Austin, TX (US)

(21) Appl. No.: 18/818,682

(22) Filed: Aug. 29, 2024

(51) Int. Cl. G06F 30/398

(52) U.S. Cl. CPC G06F 30/398

(57) ABSTRACT

Examples described herein provide a computer-implemented method for circuit design optimization that includes receiving a layout of a circuit design and calculating a congestion level of each tile in the layout and a overall congestion level for the layout.

The method also includes identifying a first tile, a first net that is at least partially disposed in the first tile, and a second tile that includes the first net, where the congestion level of the second tile is above a threshold level. The method also includes identifying a first moveable box connected to the first net and that is disposed in the second tile, creating a modified layout of the circuit design by moving the first moveable box from the second tile to the first tile, calculating a change in the congestion level for the modified layout, and updating the layout of the circuit design to the modified.

### BACKGROUND

The present invention relates generally to an improved data processing system, and in particular, to a computer implemented method for integrated circuit design. More particularly, the present invention relates to a computer implemented method, system, and computer usable program code for improved object placement in integrated circuit (IC) design.

Modern-day electronics include components that use integrated circuits. Integrated circuits are electronic circuits formed using Silicon as a substrate and by adding impurities to form solid-state electronic devices, such as transistors, diodes, and resistors. Commonly known as a “chip”, an integrated circuit is generally encased in hard plastic. The components in modern-day electronics generally appear to be rectangular black plastic pellets with connector pins protruding from the plastic encasement.

Circuit designers use a variety of software tools to design electronic circuits that accomplish an intended task. For example, a digital circuit may be designed to accept digital inputs, perform some computation, and produce a digital output. An analog circuit may be designed to accept analog signals, manipulate the analog signals, such as my amplifying, filtering, or mixing the signals, and produce an analog or digital output. Generally, any type of circuit can be designed as an IC.

The software tools used for designing ICs produce, manipulate, or otherwise work with the circuit layout at very small scales. Some of the components that such a tool may manipulate may only measure tens of nanometers across when formed in Silicon. The designs produced and manipulated using these software tools are complex, often including hundreds of thousands of such components interconnected to form an intended electronic circuitry.

The software tools manipulate these components at the components level, or blocks of components level. A block of components is also known as a cell. A tile in an IC design is a portion of the IC design. One way of identifying tiles in an IC design is to overlay a grid of imaginary vertical and horizontal lines on the design and deem each portion of the IC design bound by horizontal and vertical lines as a tile. Tiles formed in this manner are commonly known as global routing tiles. Imposing such a grid on an IC design abstracts the global routing problem away from the actual wire implementation and gives a more mathematical representation of the task.

An IC design software tool can, among other functions, manipulate tiles, or interconnect components of one tile with components of other tiles. The interconnects between components are called nets or wires. A net is a connection between parts of electronic components and is formed using a metallic material that conducts electricity.

### SUMMARY

According to an embodiment, a computer-implemented method for optimizing a circuit design is provided. The method includes receiving a layout of a circuit design and calculating a congestion level of every tile in the layout and an overall congestion level for the layout. The method also includes identifying a first tile of the plurality of tiles, identifying a first net that is at least partially disposed in the first tile, and identifying a second tile of the plurality of tiles that includes the first net, where the congestion level of the second tile is above a threshold level. The method further includes identifying a first moveable box connected to the first net and that is disposed in the second tile, creating a modified layout of the circuit design by moving the first moveable box from the second tile to the first tile, and calculating a first overall congestion level for a portion of the layout affected by creation of the modified layout prior to the modification of the layout and a second overall congestion level for the portion of the layout affected by the creation of the modified layout after the modification of the layout. Based on a determination that the second overall congestion level is less than the first overall congestion level by a threshold minimum, the method includes updating the layout of the circuit design to the modified layout of the circuit design

According to another embodiment, embodiment a system is provided. The system includes a memory comprising computer readable instructions and a processing device for executing the computer readable instructions, the computer readable instructions controlling the processing device to perform operations. The operations include receiving a layout of a circuit design and calculating the congestion level of every tile in the layout and an overall congestion level for the layout. The operations also include identifying a first tile of the plurality of tiles, identifying a first net that is at least partially disposed in the first tile, and identifying a second tile of the plurality of tiles that includes the first net, where the congestion level of the second tile is above a threshold level. The operations further include identifying a first moveable box connected to the first net and that is disposed in the second tile, creating a modified layout of the circuit design by moving the first moveable box from the second tile to the first tile, and calculating a first overall congestion level for a portion of the layout affected by creation of the modified layout prior to the modification of the layout and a second overall congestion level for the portion of the layout affected by the creation of the modified layout after the modification of the layout. Based on a determination that the second overall congestion level is less than the first overall congestion level by a threshold minimum, the operations also include updating the layout of the circuit design to the modified layout of the circuit design.

According to yet another embodiment, a computer program product for circuit design optimization is provided. The computer program product includes a set of one or more computer-readable storage media and program instructions, collectively stored in the set of one or more storage media, for causing a processor set to perform the following computer operations. The operations include receiving a layout of a circuit design and calculating the congestion level of every tile in the layout and a overall congestion level for the layout. The operations also include identifying a first tile of the plurality of tiles, identifying a first net that is at least partially disposed in the first tile, and identifying a second tile of the plurality of tiles that includes the first net, where the congestion level of the second tile is above a threshold level. The operations further include identifying a first moveable box connected to the first net and that is disposed in the second tile, creating a modified layout of the circuit design by moving the first moveable box from the second tile to the first tile, and calculating a first overall congestion level for a portion of the layout affected by creation of the modified layout prior to the modification of the layout and a second overall congestion level for the portion of the layout affected by the creation of the modified layout after the modification of the layout. Based on a determination that the second overall congestion level is less than the first overall congestion level by a threshold minimum, the operations also include updating the layout of the circuit design to the modified layout of the circuit design.

The above features and advantages, and other features and advantages, of the disclosure are readily apparent from the following detailed description when taken in connection with the accompanying drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of one or more embodiments described herein are apparent from the following detailed description taken in conjunction with the accompanying drawings in which:

FIG. 1 illustrates a computing environment, according to one or more embodiments;

FIG. 2 illustrates a flow diagram of a method for optimizing a circuit design according to one or more embodiments;

FIG. 3 illustrates a flow diagram of a method for selecting a candidate moveable box according to one or more embodiments;

FIGS. 4A, 4B, and 4C illustrate the layout of a circuit design before and after iterations of the method for optimizing a circuit design according to one or more embodiments;

FIG. 5 illustrates a flow diagram of a method for optimizing a circuit design according to one or more embodiments;

FIG. 6 is a block diagram of a system to perform circuit design optimization according to one or more embodiments;

FIG. 7 is a flow diagram of a method of fabricating an integrated circuit according to one or more embodiments; and

FIG. 8 is a pseudo-code of an algorithm for optimizing a circuit design according to one or more embodiments.

The detailed description explains embodiments of the disclosure, together with advantages and features, by way of example with reference to the drawings.

### DETAILED DESCRIPTION

During the IC design process, IC design tools generally employ various steps to produce an IC design that works as intended. A circuit designer generally creates the design in a computer programming language in the form of code. The IC design tool accepts the design in the code form and generates a rendering of the design in multiple layers that have been formed in a semiconducting material to create a circuit according to that design.

The IC design tool identifies cells in the design. The IC design tool manipulates a set of cells to legalize the design. A set of cells is one or more cells. Legalizing the design is manipulating the cells so no cells overlap each other in the rendering or when formed in the semiconducting material. A legal design results from the legalizing operation. Cells are generally allowed to touch other cells but not overlap in a legal design.

A type of tile in an IC design is known as a standard tile. A standard tile is a combination of solid-state devices, such as transistors, which take a specified number of input signals and produce a specified number of output signals, and which implement one or more circuit functions, such as logical AND, or logical OR functions. Generally, a standard tile is shaped as a rectangle that is fixed in height but variable in width. In some cases, double height tiles are also used. IC designs usually include a number of “standard rows”of standard tiles, all with the same height that matches the height of a standard tile.

A given tile includes a set of components and their interconnections. A set of components is one or more components. A tile may also include pins. A pin of a tile is a point of interconnection in the tile where a wire may be connected to couple a component of the tile with a component of another tile. In other words, the pins of a tile are the locations of input/output (I/O) to and from the tile. A set of pins for forming electrical connections in a tile is called a net. A Net list is a list of nets of a set of tiles. The interconnects are formed using wires.

Congestion is overcrowding of wires in a tile area. The illustrative embodiments recognize that placing more than the predetermined maximum number of wires in a tile area can cause congestion. The illustrative embodiments also recognize that placing wires closer than the predetermined minimum separation can also result in congestion.

Presently available IC design tools move cells and other moveable objects from one part of the design to another part of the design to achieve certain design objectives. Such movement and positioning objects in a rendering of an IC design is called placement. The placement of moveable cells is a factor in creating the congestion. For example, placing a certain movable object in a first tile may cause a certain number of wires to cross over a second tile and cause congestion in the metallic layers of the area of the second tile. However, if the movable object is placed in another tile, the number of wires crossing over the second tile may decrease, resulting in a reduction in congestion in that area.

The number of components in a chip is an indication of the density of the chip. It is not uncommon for a present chip to accommodate tens of millions of components per square millimeter. Placement problem is the problem of placing the moveable objects of a chip such that the design meets all the design parameters of the chip. As the density of the chip increases, the placement problem becomes increasingly complex. Furthermore, the probability of encountering a difficult to solve placement problem also increases with increasing density. Solving a placement problem is computationally expensive as it consumes significant time and computing resources.

Descriptions of various embodiments of the present disclosure are presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

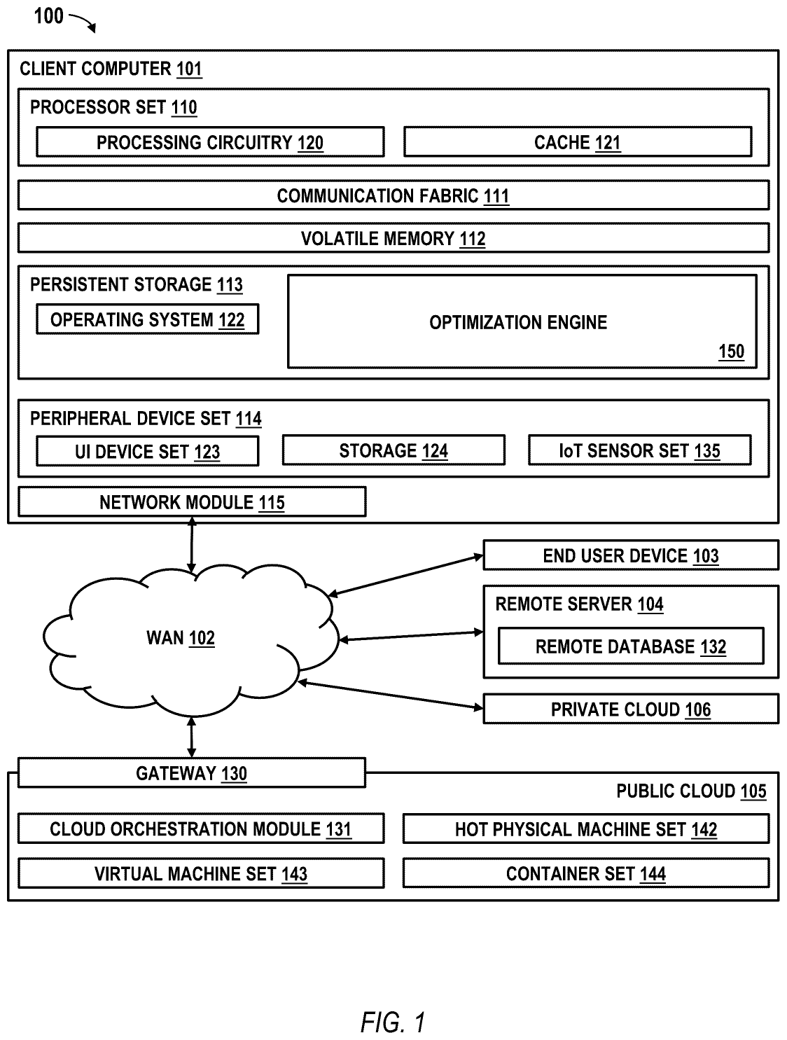

FIG. 1 illustrates a computing environment 100, according to an embodiment. Computing environment 100 contains an example of an environment for the execution of at least some of the computer code involved in performing the inventive methods, such as an optimization engine 150 for performing circuit design optimization. In addition to optimization engine 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and optimization engine 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in optimization engine 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in optimization engine 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images. ” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

According to one or more embodiments, the computing environment 100 can provide for remote data storage. For example, the computer 101 can be a cloud storage system or other suitable system for storing data that is accessible to a user remotely, such as by accessing the computer 101 using the end user device 103. That is, a user can send a user operation (also referred to as a “user request”) from the end user device 103 to the computer 101 via the WAN 102. Although the user operation may appear to be simple, such as uploading an object to a cloud storage system, the complications of operating a cloud computing system often have side effects and produce ancillary data, which may be consumed by both the operator of the system (e.g., the computer 101) and by users or other components of the cloud architecture (e.g., the computing environment 100). Ancillary data may be created by user operations that trigger the creation of the ancillary data. Ancillary data may be resource consumption information, notification data, and/or the like, including combinations and/or multiples thereof. Data for an independent event may be inferred from another event (e.g., event to update resource consumption information for an entity in a system also means that the total consumption information for the oner of the entity is also updated).

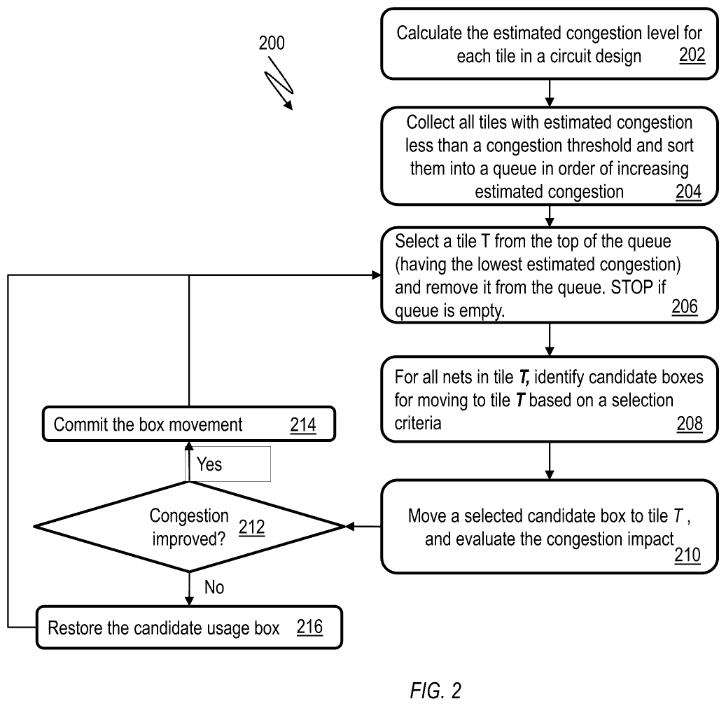

Referring now to FIG. 2, a flow diagram of a method 200 for optimizing a circuit design, according to an embodiment is shown. The method 200 can be performed by any suitable computing system, device, or environment, such as those described herein. The method 200 may be performed by the optimization engine 150 of the computing environment 100 of FIG. 1 but is not so limited.

As shown at block 202, the method 200 includes calculating an estimated congestion level for each tile in a circuit design. In exemplary embodiments, the circuit design includes a plurality of tiles that include a plurality of routing tiles, which are tiles that include one or more nets that connect components of one tile to components of another tile. In one embodiment, the estimated congestion level is only calculated for each of the plurality of routing tiles. Next, as shown at block 204, the method 200 includes collecting all of the tiles with an estimated congestion less than a congestion threshold and sorting the collected tiles into a queue in order of increasing estimated congestion.

Next, as shown at block 206, the method 200 includes selecting a tile T from the top of the queue (i.e., the tile having the lowest estimated congestion) and removing the tile from the queue. The method 200 then proceeds to block 208 and for all nets in tile T, the method 200 identifies one or more candidate boxes for moving to tile T based on a selection criteria. In exemplary embodiments, the selection criteria includes that the candidate boxes are located in a highly congested tile (e.g., a tile having a congestion level greater than a second threshold level) and based on the candidate boxes being connected to a net that is at least partially disposed in tile T. In addition, other selection criteria, such as an estimated change in wire length of moving each of the candidate boxes to tile T.

Next, as shown at block 210, the method 200 includes moving a candidate box b to tile T, and evaluating the congestion impact with the incremental router. In exemplary embodiments, the candidate box b may be selected from the candidate boxes based on the congestion level of the tile that the candidate box is located in. For example, the selected candidate box may be selected from the tile having the highest congestion level. In some embodiments, an estimated change in the length of the net that connects to the candidate boxes may be utilized to select the candidate box.

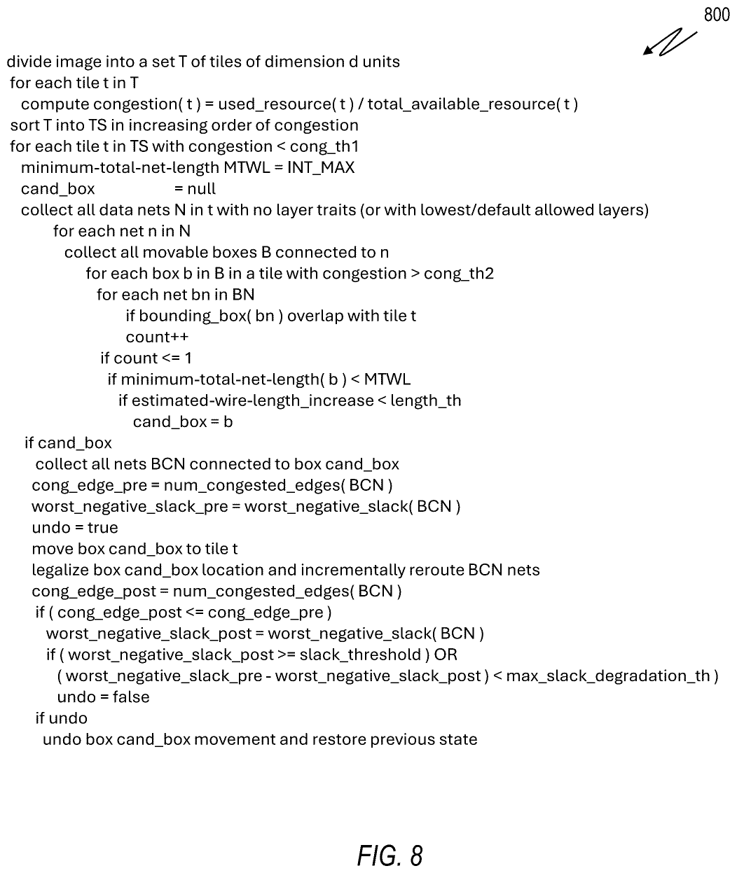

As illustrated at decision block 212, the method 200 includes determining whether moving the selected candidate box to tile T improves the congestion of the circuit design. In exemplary embodiments, the determination of whether moving the selected candidate box to tile T improves the congestion of the circuit design is made by comparing the overall congestion of the circuit design before moving the candidate box to the overall congestion of the circuit design after moving the candidate box. In exemplary embodiments, the overall congestion is calculated as the average congestion of the tiles of a layer of the integrated circuit design. Based on a determination that moving the selected candidate box to tile T improves the congestion of the circuit design, the method 200 proceeds to block 214, and the circuit design is updated to commit the movement of the selected candidate box to tile T. In an exemplary embodiment, the determination of local congestion improvement is based on the movement of a box from one tile to another, as shown in FIG. 8. Otherwise, the method 200 proceeds to block 216 and the movement of the selected candidate box to tile T is discarded.

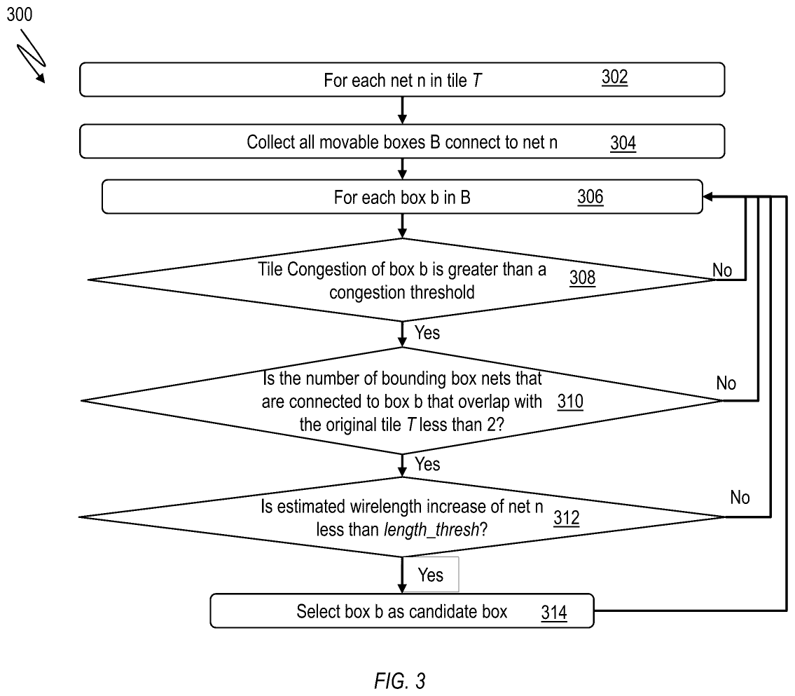

Referring now to FIG. 3, a flow diagram of a method 300 for selecting a candidate moveable box according to one or more embodiments is shown. The method 300 can be performed by any suitable computing system, device, or environment, such as those described herein. The method 300 may be performed by the optimization engine 150 of the computing environment 100 of FIG. 1 but is not so limited.

As shown at block 302, the method 300 includes identifying each net n in a tile T. In exemplary embodiments, tile T is the tile of the circuit design that has a lowest congestion level. Next, as shown at block 302, the method 300 includes identifying all moveable boxes B that are connected to net n. The method 300 then proceeds to block 306 and iteratively evaluates each box b of boxes B. At decision block 308, it is determined whether the congestion level of a tile that includes box b is greater than a congestion threshold. If the congestion level of a tile that includes box b is not greater than a congestion threshold, box b is not selected, and the method 300 returns to block 306 to evaluate another box. At decision block 310, a determination is made whether the number of bounding box of nets that are connected to box b that overlap tile T is less than 2. If the number of the overlap count is more than 1, box b can't be chosen and the method 300 returns to block 306 to evaluate another box. Otherwise, as shown at decision block 312, the method 300 includes determining whether an estimated increase in the wirelength of net n for moving box b to tile T is less than a threshold length. If the estimated increase in the wirelength of net n for moving box b to tile T is greater than a threshold length, box b is not selected and the method 300 returns to block 306 to evaluate another box. At block 314, the method 300 includes selecting box b as a candidate box to move to tile T.

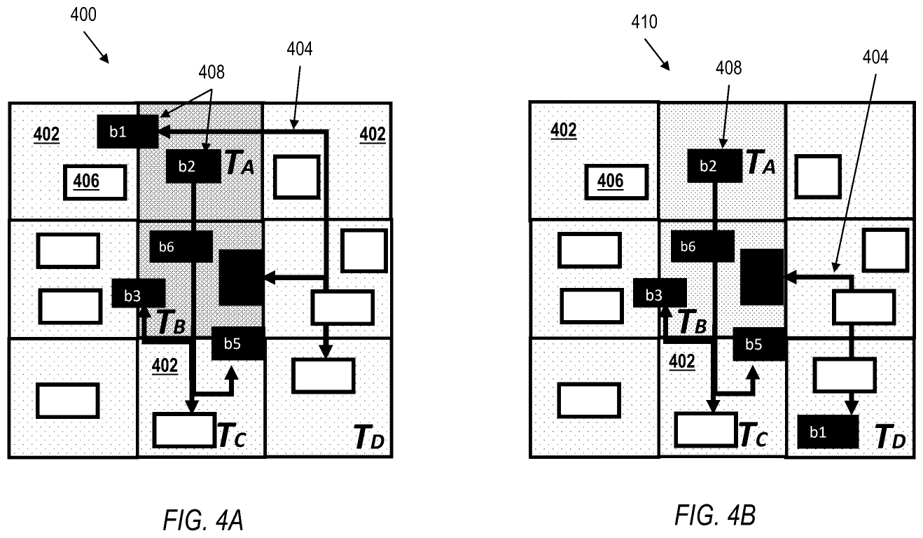

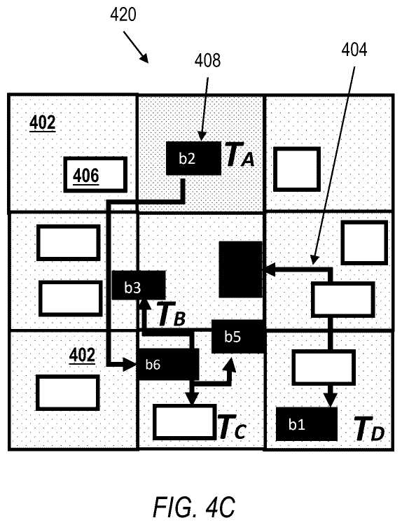

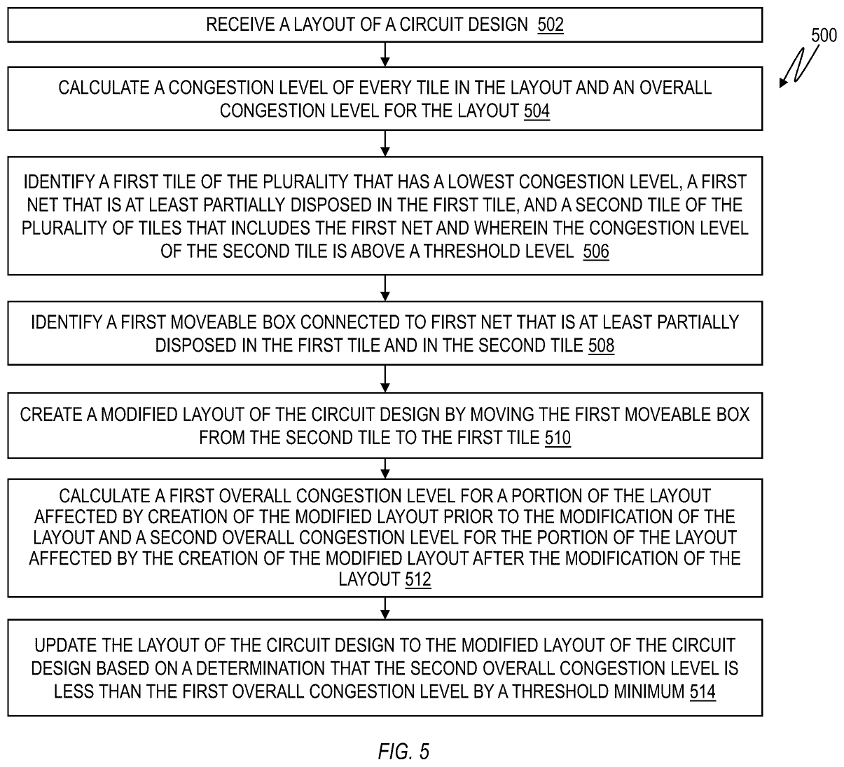

Referring now to FIGS. 4A, 4B, and 4C, layouts of a circuit designs 400, 410, and 420 before and after iterations of the method for optimizing a circuit design according to one or more embodiments are respectively shown. As illustrated, the circuit designs 400, 410 include a plurality of tiles 402 that may include one or more moveable boxes 408, one or more non-moveable boxes 406, and one or more nets 404 that connect moveable boxes 408 and/or non-moveable boxes 406. In exemplary embodiments, a congestion level is calculated for each of the plurality of tiles 402. In the illustrated example, tiles T_{A} and T_{B} in circuit design 400 have a high level of congestion while the remaining tiles in circuit design 400 have a low level of congestion. In exemplary embodiments, the circuit design 400 is modified using one of the method 200 shown in FIG. 2 and the method 500 shown in FIG. 5 to generate the circuit design 410. As shown, the circuit design 400 has been modified by moving moveable box b1 from tile T_{A} to box T_{D}. As a result, the congestion level of tile T_{A} has been reduced from a high level of congestion as shown in circuit design 400 to a moderate level as shown in circuit design 410. As illustrated, the congestion level of tile T_{B} remains unchanged between circuit design 400 and circuit design 410. In exemplary embodiments, as shown in FIG. 4C, an additional iteration of the method for optimizing a circuit design according to one or more embodiments results in the movement of moveable box b6 from tile T_{B} to tile T_{C} to reduce the congestion level of tile T_{B}. As a result, the congestion level of tile T_{B} has been reduced from a high level of congestion as shown in circuit design 400 to a low level as shown in circuit design 420. For example, moving box b6 from tile T_{B} to tile T_{C} reduces the congestion in tile T_{B} by moving the connection from box b2 to box b6 to avoid going through the congested tile T_{B}.

Referring now to FIG. 5, a flow diagram of a method 500 for optimizing a circuit design according to one or more embodiments is shown. The method 500 can be performed by any suitable computing system, device, or environment, such as those described herein. The method 500 may be performed by the optimization engine 150 of the computing environment 100 of FIG. 1 but is not so limited.

As shown at block 502, the method 500 begins by receiving a layout of a circuit design. In exemplary embodiments, the layout of the circuit design includes a plurality of tiles which may include one or more moveable boxes, non-moveable boxes, and one or more nets that connect the moveable and non-moveable boxes. Next, as shown at block 504, the method 500 includes calculating a congestion level of every tile in the layout and an overall congestion level for the layout. In one embodiment, the overall congestion level for the layout is calculated as the average congestion levels of the tiles in the layout.

At block 506, the method 500 includes identifying a first tile of the plurality that has the lowest congestion level, a first net that is at least partially disposed in the first tile, and a second tile of the plurality of tiles that includes the first net. In one embodiment, the second tile is identified as the tile having the highest congestion level that includes the first net. In exemplary embodiments, the second tile is identified based on a determination that the congestion level of the second tile is above a threshold level. In exemplary embodiments, the threshold level is a threshold congestion level that may be set by a user of an IC design tool. In exemplary embodiments, identifying the second tile includes identifying a group of tiles from the plurality of tiles that include the net and selecting the second tile from the group based on the congestion level of the second tile.

Next, at block 508, the method 500 includes identifying a first moveable box that is connected to the first net and that is disposed in the second tile. The method 500 also includes creating a modified layout of the circuit design by moving the first moveable box from the second tile to the first tile, as shown at block 510. Next, as shown at block 512, the method 500 includes calculating a first overall congestion level for a portion of the layout affected by creation of the modified layout prior to the modification of the layout and a second overall congestion level for the portion of the layout affected by the creation of the modified layout after the modification of the layout. In exemplary embodiments, the portion of the layout affected by the creation of the modified layout includes the first tile, the second tile, and all tiles that include the first net.

At block 514, the method 500 includes updating the layout of the circuit design to the modified circuit design based on a determination that the second overall congestion level is less than the first overall congestion level by a threshold minimum. Based on a determination that that the second overall congestion level is not less than the first overall congestion level by a threshold minimum, the method includes identifying a second moveable box that is connected to the first net and is disposed in one of the second tile and a third tile, wherein the congestion level of the third tile is above the threshold level. After the second moveable box is identified, the method 500 returns to block 510 and creates another modified layout of the circuit design by moving the second moveable box to the first tile.

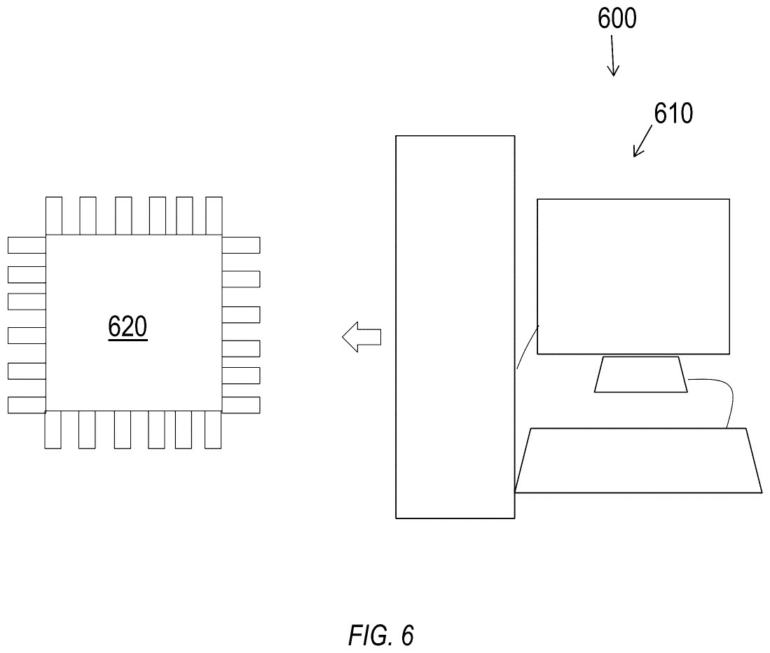

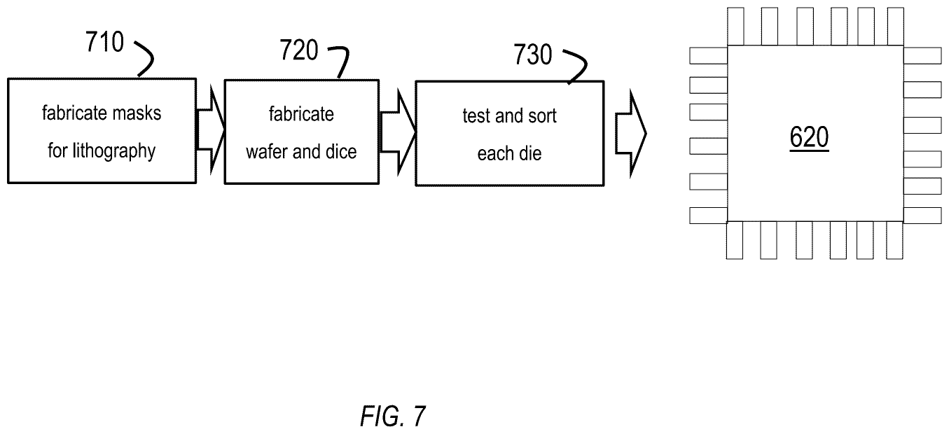

FIG. 6 is a block diagram of a system 600 to perform circuit design optimization according to one or more embodiments. The system 600 includes processing circuitry 610 used to generate the circuit design that is ultimately fabricated into an integrated circuit 620. The steps involved in the fabrication of the integrated circuit 620 are well-known and briefly described herein. Once the physical layout is finalized, based, in part, on the circuit design optimization according to one or more embodiments, the finalized physical layout is provided to a foundry. Masks are generated for each layer of the integrated circuit based on the finalized physical layout. Then, the wafer is processed in the sequence of the mask order. The processing includes photolithography and etch. This is further discussed with reference to FIG. 7.

Particularly, FIG. 7 is a flow diagram of a method 700 of fabricating an integrated circuit according to one or more embodiments. Once the physical design data is obtained, based, in part, on performing circuit design optimization as described herein, the integrated circuit 620 can be fabricated according to known processes that are generally described with reference to FIG. 7. Generally, a wafer with multiple copies of the final design is fabricated and cut (i.e., diced) such that each die is one copy of the integrated circuit 620. At block 710, the processes include fabricating masks for lithography based on the finalized physical layout. At block 720, fabricating the wafer includes using the masks to perform photolithography and etching. Once the wafer is diced, testing and sorting each die is performed, at block 730, to filter out any faulty die.

Referring now to FIG. 8, pseudo-code of an algorithm 800 for optimizing a circuit design according to one or more embodiments is shown. As will be appreciated by those of ordinary skill in the art, the algorithm 800 is exemplary in nature and is not intended to be limiting in any way.

While the foregoing is directed to embodiments of the present disclosure, other and further embodiments of the present disclosure may be devised without departing from the basic scope thereof, and the scope thereof is determined by the claims that follow.

What is claimed is:

1. A computer-implemented method for circuit design optimization, the method comprising:
receiving a layout of a circuit design;
calculating a congestion level of each tile in the layout ;
identifying a first tile in the layout;
identifying a first net that is at least partially disposed in the first tile;
identifying a second tile in the layout that includes the first net, wherein the congestion level of the second tile is above a threshold level;
identifying a first moveable box connected to the first net and that is disposed in the second tile;
creating a modified layout of the circuit design by moving the first moveable box from the second tile to the first tile;
calculating a first overall congestion level for a portion of the layout affected by creation of the modified layout prior to the modification of the layout and a second overall congestion level for the portion of the layout affected by the creation of the modified layout after the modification of the layout; and
updating the layout of the circuit design to the modified layout of the circuit design based on a determination that the second overall congestion level is less than the first overall congestion level by a threshold minimum.

2. The computer-implemented method of claim 1, wherein identifying the second tile includes identifying a group of tiles in the layout that include the net and selecting the second tile from the group based on the congestion level of the second tile.

3. The computer-implemented method of claim 2, wherein the congestion level of the second tile is a highest congestion level of the group of tiles in the layout.

4. The computer-implemented method of claim 1, wherein based on a determination the second overall congestion level is not less than the first overall congestion level by the threshold minimum, the method further comprises:
identifying a second moveable box that is connected to the first net and that is disposed in one of the second tile and a third tile, wherein the congestion level of the third tile is above the threshold level;
creating a second modified layout of the circuit design by moving the second moveable box to the first tile; and
calculating a third overall congestion level for the portion of the layout affected by the creation of the second modified layout after the modification of the layout; and
updating the layout of the circuit design to the modified layout of the circuit design based on a determination that the third overall congestion level is less than the first overall congestion level by the threshold minimum.

5. The computer-implemented method of claim 1, further comprising calculating a change in a wire length of the first net caused by moving the first moveable box from the second tile to the first tile.

6. The computer-implemented method of claim 5, wherein based on a determination that the change in the wire length of the first net exceeds a threshold maximum, the method further comprises:
identifying a second moveable box that is connected to the first net and that is disposed in one of the second tile and a third tile, wherein the congestion level of the third tile is above the threshold level;
creating a second modified layout of the circuit design by moving the second moveable box to the first tile; and
calculating a third overall congestion level for the portion of the layout affected by the creation of the second modified layout after the modification of the layout; and
updating the layout of the circuit design to the modified layout of the circuit design based on a determination that the third overall congestion level is less than the first overall congestion level by the threshold minimum.

7. The computer-implemented method of claim 1, wherein the first tile is identified as having a lowest congestion level among the tiles in the layout.

8. The computer-implemented method of claim 1, wherein the portion of the layout affected by the creation of the modified layout include the first tile, the second tile, and all tiles that include the net.

9. A system comprising:
a memory comprising computer readable instructions; and
a processing device for executing the computer readable instructions, the computer readable instructions controlling the processing device to perform operations comprising:
receiving a layout of a circuit design;
calculating a congestion level of tile in the layout and a overall congestion level for the layout;
identifying a first tile in the layout;
identifying a first net that is at least partially disposed in the first tile;
identifying a second tile in the layout that includes the first net, wherein the congestion level of the second tile is above a threshold level;
identifying a first moveable box connected to the first net and that is disposed in the second tile;
creating a modified layout of the circuit design by moving the first moveable box from the second tile to the first tile; and
calculating a first overall congestion level for a portion of the layout affected by creation of the modified layout prior to the modification of the layout and a second overall congestion level for the portion of the layout affected by the creation of the modified layout after the modification of the layout; and
updating the layout of the circuit design to the modified layout of the circuit design based on a determination that the first overall congestion minus the second overall congestion is greater than a threshold minimum.

10. The system of claim 9, wherein identifying the second tile includes identifying a group of tiles from tiles in the layout that include the net and selecting the second tile from the group based on the congestion level of the second tile.

11. The system of claim 9, wherein the congestion level of the second tile is a highest congestion level of the tiles in the layout.

12. The system of claim 9, wherein based on a determination the second overall congestion level is not less than the first overall congestion level by the threshold minimum, the operations further comprise:
identifying a second moveable box that is connected to the first net and that is disposed in one of the second tile and a third tile, wherein the congestion level of the third tile is above the threshold level;
creating a second modified layout of the circuit design by moving the second moveable box to the first tile; and
calculating a third overall congestion level for the portion of the layout affected by the creation of the second modified layout after the modification of the layout; and
updating the layout of the circuit design to the modified layout of the circuit design based on a determination that the third overall congestion level is less than the first overall congestion level by the threshold minimum.

13. The system of claim 9, wherein the operations further comprise calculating a change in a wire length of the first net caused by moving the first moveable box from the second tile to the first tile.

14. The system of claim 13, wherein based on a determination that the change in the wire length of the first net exceeds a threshold maximum, the operations further comprise:
identifying a second moveable box that is connected to the first net and that is disposed in one of the second tile and a third tile, wherein the congestion level of the third tile is above the threshold level;
creating a second modified layout of the circuit design by moving the second moveable box to the first tile; and
calculating a third overall congestion level for the portion of the layout affected by the creation of the second modified layout after the modification of the layout; and
updating the layout of the circuit design to the modified layout of the circuit design based on a determination that the third overall congestion level is less than the first overall congestion level by the threshold minimum.

15. The system of claim 9, wherein the first tile is identified as having a lowest congestion level among the tiles in the layout.

16. The system of claim 9, wherein the portion of the layout affected by the creation of the modified layout include the first tile, the second tile, and all tiles that include the net.

17. A computer program product for circuit design optimization, the computer program product comprising:
a set of one or more computer-readable storage media;
program instructions, collectively stored in the set of one or more storage media, for causing a processor set to perform the following computer operations:
receiving a layout of a circuit design;
calculating a congestion level of tile in the layout in the layout and a overall congestion level for the layout;
identifying a first tile in the layout;
identifying a first net that is at least partially disposed in the first tile;
identifying a second tile in the layout that includes the first net, wherein the congestion level of the second tile is above a threshold level;
identifying a first moveable box connected to the first net and that is disposed in the second tile;
creating a modified layout of the circuit design by moving the first moveable box from the second tile to the first tile; and
calculating a first overall congestion level for a portion of the layout affected by creation of the modified layout prior to the modification of the layout and a second overall congestion level for the portion of the layout affected by the creation of the modified layout after the modification of the layout; and
updating the layout of the circuit design to the modified layout of the circuit design based on a determination that the second overall congestion level is less than the first overall congestion level by a threshold minimum.

18. The computer program product of claim 17, wherein identifying the second tile includes identifying a group of tiles from the tiles in the layout that include the net and selecting the second tile from the group based on the congestion level of the second tile.

19. The computer program product of claim 17, wherein the congestion level of the second tile is a highest congestion level of the tiles in the layout.

20. The computer program product of claim 17, wherein based on a determination that the second overall congestion level is not less than the first overall congestion level by the threshold minimum, the operations further comprise:
identifying a second moveable box that is connected to the first net and that is disposed in one of the second tile and a third tile, wherein the congestion level of the third tile is above the threshold level;
creating a second modified layout of the circuit design by moving the second moveable box to the first tile; and
calculating a third overall congestion level for the portion of the layout affected by the creation of the second modified layout after the modification of the layout; and
updating the layout of the circuit design to the second modified layout of the circuit design based on a determination that the first overall congestion level minus the third overall congestion level is greater than the threshold minimum.
